(19) United States
(12) Patent Application Publication
(10) Pub. No.: US 2006/0186504 A1
(43) Pub. Date: Aug. 24, 2006

(54) CMOS image sensor for reducing partition noise

(75) Inventors: Chang-Min Bae, Cheongju-si (KR); Kyung-Jin Shim, Cheongju-si (KR)

Correspondence Address: Fernandez & Associates, LLP, PO Box D, Menlo Park, CA, 94025-6204, US

(73) Assignee: MagnaChip Semiconductor Ltd., Seoul (KR)

(21) Appl. No.: 11/351,438

(22) Filed: Feb. 10, 2006

(30) Foreign Application Priority Data
Feb. 24, 2005 (KR) 10-2005-0015520

(51) Int. Cl. H01L 31/06

(52) U.S. Cl. 257/462

(57) ABSTRACT

A CMOS image sensor according to an embodiment of the present invention includes a unit pixel, including a transfer transistor controlled by a transfer control signal; and a transfer control signal controller for controlling a rising and a falling times of the transfer control signal, wherein the falling time of the transfer control signal is sufficiently increased to reduce a partition noise.

### FIELD OF THE INVENTION

The present invention relates to a CMOS image sensor; and, more particularly, to a CMOS image sensor for reducing a partition noise by extending a falling time of a transfer control signal applied to a gate of a transfer transistor.

### DESCRIPTION OF THE RELATED ART

An image sensor is a semiconductor device that converts an optical image into an electric signal. The image sensor is classified into a charge coupled device (hereinafter, referring to a CCD) image sensor and a complementary metal oxide semiconductor (hereinafter, referring to a CMOS) image sensor.

The CCD image sensor includes at least one. The MOS capacitors are arranged very close to one another, and charge carriers are stored in the MMOS capacitors and transferred thereto.

On the contrary, the CMOS image sensor includes a plurality of unit pixels fabricated through CMOS processes. Each of the unit pixels includes one photodiode and three or four MOS transistors for driving the unit pixel. The CMOS image sensor employs CMOS technology that uses a control circuit and a signal processing circuit as a peripheral circuit. The MOS transistors are formed based on the number of pixels, and output data are successively detected using the MOS transistors.

In fabricating these various kinds of image sensors, many attempts to increase photosensitivity have been made. One of them is a light integrating technology. For example, the CMOS image sensor includes a photodiode for sensing light and a CMOS logic circuit for processing the sensed light into an electric data signal. In order to increase photosensitivity, an attempt to increase a fill factor has been made. The fill factor means a ratio of a photodiode with respect to a total area of the image sensor.

FIG. 1 is a circuit diagram showing a unit pixel of a CMOS image sensor, in which the unit pixel includes four transistors.

The unit pixel of FIG. 1 is formed using a sub-micron CMOMS epitaxial process so as to increase photosensitivity and reduce crosstalk effect between unit pixels.

As shown, the unit pixel of the image sensor includes a photodiode PD constructing a PNP junction, a PNPN junction or the like, a transfer transistor TX, a floating diffusion node FD, a reset transistor RX, a drive transistor DX, and a select transistor SX. The photodiode PD receives light from an abject to generate corresponding electron-hole pairs, i.e., photogenerated charges. The transfer transistor TX transfers the photogenerated charges accumulated at the photodiode PD to the floating diffusion node FD when the transfer transistor TX is turned on. The floating diffusion node FD receives the photogenerated charges transferred from the transfer transistor TX when the transfer transistor TX is turned on. The reset transistor RX resets a voltage of the floating diffusion node FD to a power voltage VDD level in response to a reset signal. An amount of turning on a gate of the drive transistor DX is varied with an electric signal corresponding to the photogenerated charges transferred from the floating diffusion node FD, so that the drive transistor DX outputs the electric signal in proportion to the amount of the photogenerated charges. The select transistor SX, which is turned on based on a select signal, outputs a signal of the unit pixel outputted through the drive transistor DX.

As shown in FIG. 1, a reference numeral LX represents a load transistor. The floating diffusion node FD has a predetermined capacitance Cfd.

An operation principle of obtaining an output voltage VOUT from the unit pixel illustrated in FIG. 1 will be described below in detail.

First, the transfer transistor TX, the reset transistor RX, and the select transistor SX are turned off. At this time, the photodiode PD is in a fully depletion state. A light integration is started to collect the photogenerated charges at the photodiode PD.

The voltage of the floating diffusion node FD is reset as the reset transistor RX is turned on. Then, the select transistor SX is turned on. At this time, a first output voltage V1 of the unit pixel at a reset operation is measured. The measured value means a DC level shift of the voltage of the floating diffusion node FD.

After an appropriate light integration time, the transfer transistor TX is turned on so that all the photogenerated charges at the photodiode PD are transferred to the floating diffusion node FD. Then, the transfer transistor TX is turned off. At this time, a second output voltage V2 due to the charges transferred to the floating diffusion node FD is measured.

The output voltage VOUT, which is a transfer result of the photogenerated charges, is obtained from the difference between the output voltage V1 and the output voltage V2. That is, the output voltage VOUT is purely a signal voltage except for a noise. This method is referred to as a correlated double sampling (CDS).

The transfer transistor TX transfers the photogenerated charges to the floating diffusion node FD. Meanwhile, the transfer transistor TX has several problems when a transfer control signal applied to a gate of a transfer transistor is dropped from a logic level ‘HIGH’ to a logic level ‘LOW’, that is, when it changes from a turned-on state to a turned-off state.

The biggest problem is a partition noise caused by a charge injection to the floating diffusion node FD, which occurs due to a short falling time of the transfer control signal.

FIG. 2 is an energy diagram describing the CMOS image sensor, centering on the transfer transistor TX, and FIG. 3 is an energy diagram illustrating an electron movement when the transfer transistor TX is turned on.

As shown, when the transfer transistor TX is in the turned-off state, the photogenerated charges are accumulated at the photodiode PD. When the transfer transistor TX is turned on, the photogenerated charges are transferred from the photodiode PD to the floating diffusion node FD along a path ‘A’.

FIG. 4 is an energy diagram depicting an electron movement in case that a falling time of the transfer control signal applied to the transfer transistor TX is short when the transfer transistor TX is turned off.

After the transfer transistor TX is turned off, the photogenerated charges accumulated in the floating diffusion node FD are converted into an electric signal. When the transfer transistor TX is turned off, channel electrons existing under the transfer transistor TX may be moved in an arbitrary direction.

Since the voltage of the floating diffusion node FD is higher than that of the photodiode PD, it is theoretically right that the channel electrons move from the photodiode PD to the floating diffusion node FD, as indicated by a path ‘B’ in FIG. 4. However, since the turn-off time of the transfer transistor TX is very short, all channel electrons cannot move to the floating diffusion node ND. That is, some channel electrons return back to the photodiode PD, as indicated by a path ‘C’ in FIG. 4.

This phenomenon occurs differently in pixels. Therefore, when seen from the outside, it appears that noise occurs. This phenomenon is called a partition noise. Since the partition noise is considered as noise on a screen, it acts as a factor that degrades a performance of the image sensor.

### SUMMARY OF THE INVENTION

It is, therefore, an object of the present invention to provide a CMOS image sensor for reducing a partition noise caused by a short falling time of a transfer control signal applied to a gate of a transfer transistor.

In accordance with an aspect of the present invention, there is provided a CMOS image sensor including: a unit pixel, including a transfer transistor controlled by a transfer control signal; and a transfer control signal controller for controlling a rising and a falling times of the transfer control signal, wherein the falling time of the transfer control signal is sufficiently increased to reduce a partition noise.

In accordance with another aspect of the present invention, there is provided a CMOS image sensor including: a plurality of unit pixels arranged in a column X a row form, each including a transfer transistor controlled by a transfer control signal; and a transfer control signal controller for controlling a rising and a falling times of the transfer control signal; and a plurality of capacitive parts connected between a ground voltage and a common node which is connected between an output terminal of the transfer control signal controller and gates of the transfer transistors to thereby increase the falling time of the transfer transistor when the transfer transistors contained in the unit pixels of the same row are turned off, wherein, the plural unit pixels are disposed in the same row being controlled by the single transfer control signal controller.

### BRIEF DESCRIPTION OF THE DRAWINGS

The above and other objects and features of the present invention will become apparent from the following description of the preferred embodiments given in conjunction with the accompanying drawings, in which:

FIG. 1 is a circuit diagram showing a unit pixel of a CMOS image sensor, in which the unit pixel has four transistors;

FIG. 2 is an energy diagram describing the CMOS image sensor, centering on a transfer transistor;

FIG. 3 is an energy diagram illustrating an electron movement when the transfer transistor is turned on;

FIG. 4 is an energy diagram depicting an electron movement in case where a falling time of a transfer control signal is short when the transfer transistor TX is turned off;

FIG. 5 is an energy diagram showing an electron movement when a falling time of a transfer control signal is increased;

FIG. 6 is a diagram illustrating a CMOS type driver for driving a transfer transistor of a unit pixel, a structure of unit pixels, and a falling timing of the CMOS type driver;

FIGS. 7A to 7C are circuit diagrams describing a driver for controlling a transfer control signal applied to a gate of a transfer transistor in accordance with a first embodiment of the present invention;

FIGS. 8A to 8C are timing diagrams illustrating a variation of a falling time in a simulation of the transfer transistor in accordance with the first embodiment of the present invention;

FIGS. 9 and 10 are diagram depicting a CMOS type driver for driving a transfer transistor of a unit pixel in accordance with a second embodiment of the present invention;

FIGS. 11A to 11C are circuit diagrams showing a driver for driving a transfer transistor in accordance with a third embodiment of third embodiment of the present invention; and

FIGS. 12A to 12C are layouts describing the driver shown in FIGS. 11A to 11C.

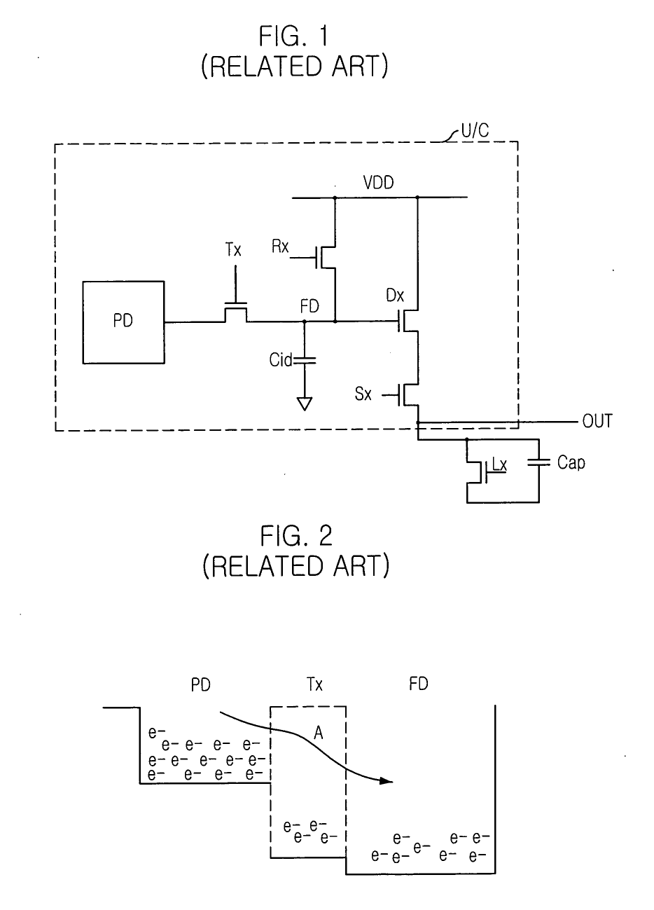

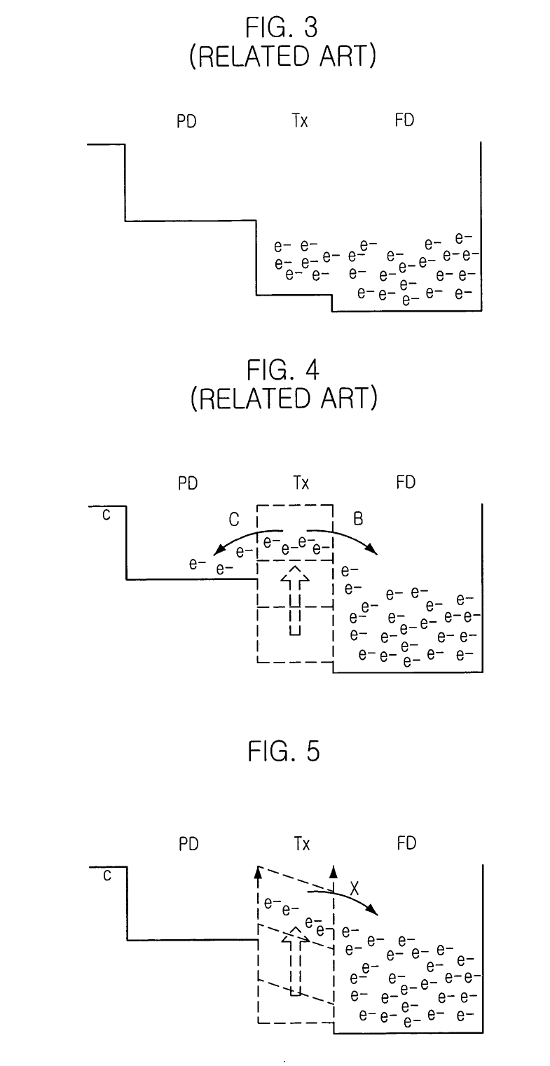

### DETAILED DESCRIPTION OF THE INVENTION

A CMOS image sensor in accordance with exemplary embodiments of the present invention will be described in detail with reference to the accompanying drawings.

Since partition noise is caused by a short falling time of a transfer control signal applied to a gate of a transfer transistor, the present invention focuses on increasing the falling time of the transfer control signal.

During the increased falling time, a time margin for generation of an electric field allowing channel electrons to move to a floating diffusion node higher than the photodiode is increased. All channel electrons move to the floating diffusion node due to the electric field, thereby reducing partition noise.

Generally, the falling time “τ” is defined as τ=RC. Therefore, at least one of R and C is also increased.

FIG. 5 is an energy diagram showing an electron movement when a falling time of a transfer control signal increases.

As shown, if the falling time increases, the time for generation of the electric field under the channel is increased as much as the increased falling time. As indicated by a path ‘X’, all channel electrons move to the floating diffusion node FD according to the slope of the electric field, thereby preventing occurrence of partition noise.

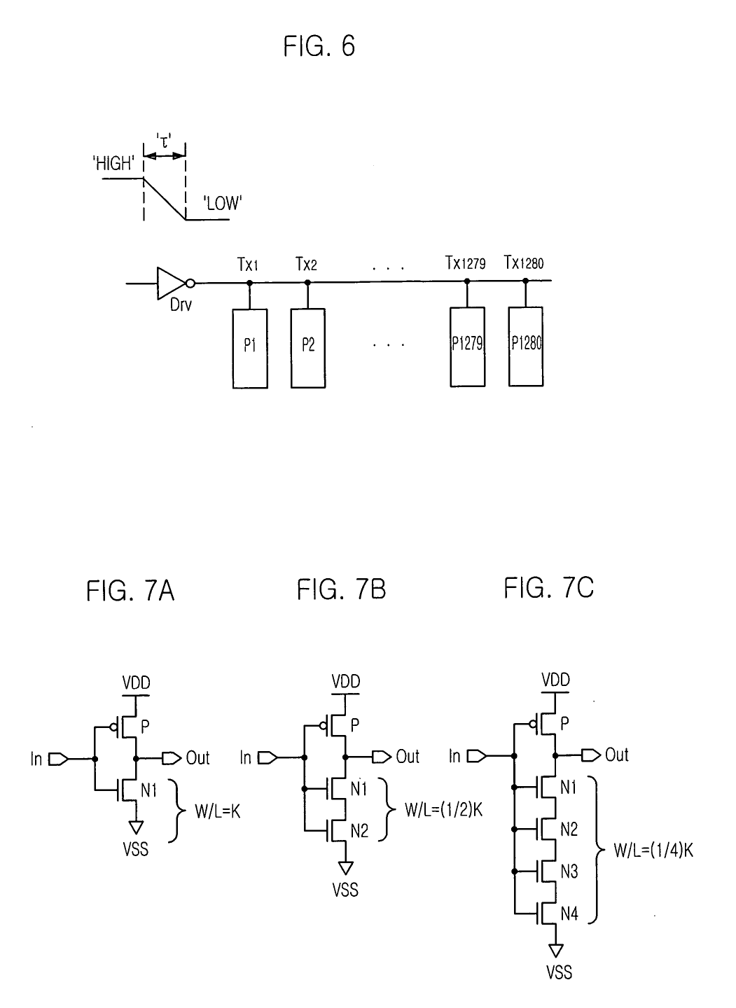

FIG. 6 is a diagram illustrating a CMOS type driver for driving a transfer transistor of a unit pixel, a structure of unit pixels, and a falling timing of the CMOS type driver.

As shown, the CMOS image sensor includes a plurality of unit pixels P1 to P1280 and the CMOS type driver DRV. Each of the unit pixels P1 to P1280 includes a photodiode, a floating diffusion node, a transfer transistor, a reset transistor, a drive transistor, and a select transistor. The CMOS type driver DRV controls an on operation and an off operation of the transfer transistors TX1 to TX1280 contained in the unit pixels.

A CMOS inverter type driver is illustrated as an example of the CMOS type driver DRV. The plurality of unit pixels P1 to P1280 are disposed in a single row. Accordingly, the CMOS type driver DRV simultaneously controls the plurality of transfer transistors TX1 to TX1280 of the unit pixels disposed in the single row.

Herein, the arrangement of the 1280 unit pixels in the single row is a 1.3M image sensor. Also, in this embodiment, the reset transistor and the select transistor of the unit pixel are driven by one driver in each row.

Hereinafter, embodiments for increasing the falling time (τ) when the transfer transistor is turned off will be described in detail with reference to the accompanying drawings.

### Embodiment 1

A first embodiment is to increase the falling time of the transfer control signal applied to the gate of the transfer transistor by reducing a W/L ratio of an NMOS transistor of the CMOS type driver DRV.

FIGS. 7A to 7C are circuit diagrams describing a driver for controlling the transfer transistor in accordance with the first embodiment of the present invention.

A CMOS inverter type driver illustrated in FIG. 7A includes a PMOS transistor P and an NMOS transistor N connected in series between a power voltage VDD and a ground voltage VSS. The CMOS inverter type driver receives an input signal IN through gates of the two transistors to output an inverted signal OUT.

It is assumed that the W/L ratio of the NMOS transistor N is K, a resistance can be increased, i.e., a current is decreased, by increasing the length L or decreasing the width W, thereby increasing the falling time of the transfer control signal.

Meanwhile, the width W of the gate electrode is related to the design rule of the device. Accordingly, a method of reducing the W/L ratio without modifying the design rule is to increase the length L of the gate electrode when the width W of the NMOS transistor is fixed.

Referring to FIG. 7B, a half of K, i.e., W/2L, can be obtained by serially connecting the two NMOS transistors N1 and N2. This can increase the length L of the NMOS transistor and is efficient for space utilization in the layout design.

Referring to FIG. 7C, a quarter of K, i.e., W/4L, can be obtained by serially connecting four NMOS transistors N1 to N4. That is, desired falling time can be obtained by serially connecting NMOS transistors as many as required.

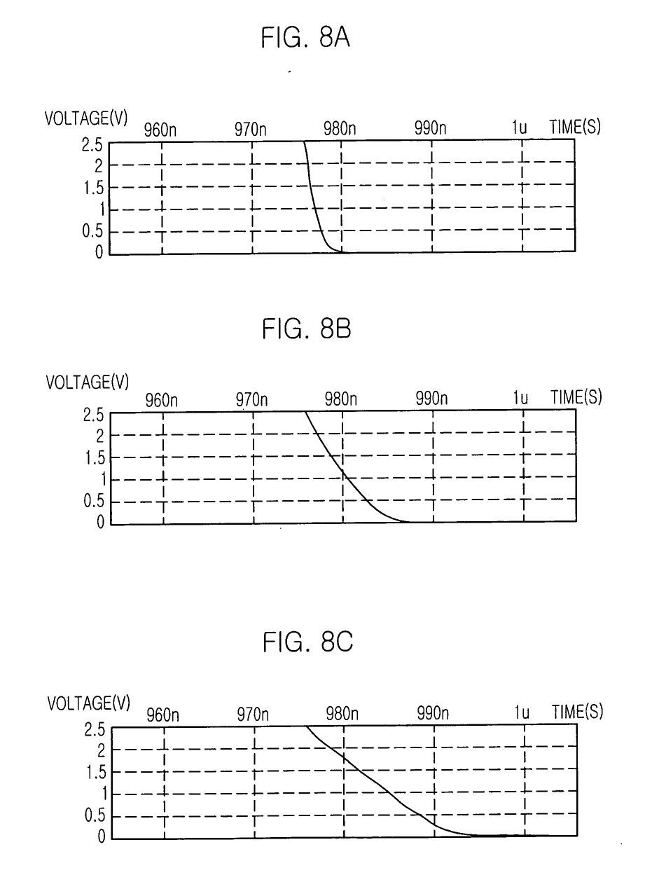

FIGS. 8A to 8C are timing diagrams illustrating a variation of the falling time in the simulation of the transfer transistor in accordance with the first embodiment of the present invention.

Referring to FIG. 8A, when one NMOS transistor N is used so that the W/L ratio is K, the falling time is about 4 ns.

Meanwhile, since the falling time of the transfer control signal applied to the gate of the transfer transistor in the 1.3M CMOS image sensor is 2-3 ns, the falling time in FIG. 8A is increased compared with the conventional case.

Referring to FIG. 8B, when two NMOS transistors N1 and N2 are used so that the W/L ratio is the half of K, the falling time is about 8 ns.

Referring to FIG. 8C, when four NMOS transistors N1 to N4 are used so that the W/L ratio is the quarter of K, the falling time is about 17.9 ns.

### Embodiment 2

A second embodiment is to increase a falling time (τ) of a transfer transistor by increasing a capacitance C.

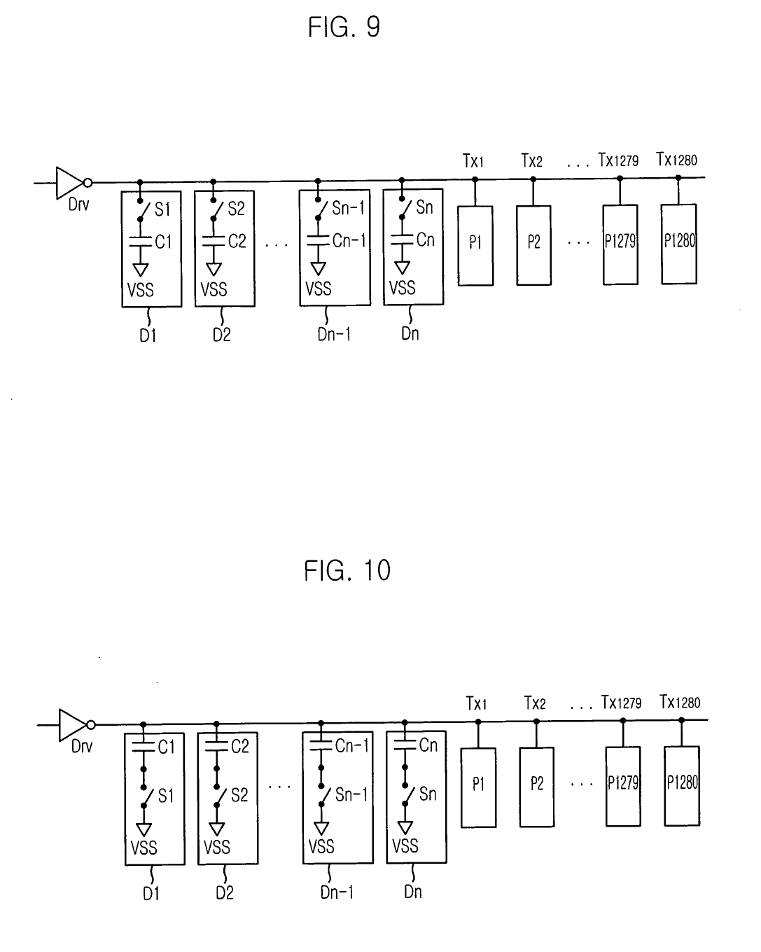

FIGS. 9 and 10 are diagrams depicting a CMOS type driver for driving a transfer transistor in accordance with a second embodiment of the present invention.

As shown, the CMOS image sensor includes a plurality of unit pixels P1 to P1280 and a CMOS type driver DRV. Each of the unit pixels P1 to P1280 includes a photodiode, a floating diffusion node, a transfer transistor, a reset transistor, a drive transistor, and a select transistor. The CMOS type driver DRV controls the on operation and the off operation of the transfer transistors TX1 to TX1280 contained in the unit pixels.

A CMOS inverter type driver is illustrated as an example of the CMOS type driver DRV. The plurality of unit pixels P1 to P1280 are disposed in a single row. Accordingly, the CMOS type driver DRV simultaneously controls the plurality of transfer transistors TX1 to TX1280 of the unit pixels disposed in the single row.

Herein, the arrangement of the 1280 unit pixels in the single row is a 1.3M image sensor. Also, in this embodiment, the reset transistor and the select transistor of the unit pixel are driven by one driver in each row.

That is, in order to increase the falling time (τ) of the transfer control signal applied to the gate of the transfer transistor, a plurality of capacitive part D1 to Dn are connected between a ground voltage VSS and a common node of an output terminal of the driver DRV and gates of the transfer transistors TX1 to TX1280.

Each of the capacitive parts D1 to Dn includes a plurality of capacitors C1 to Cn and a plurality of switches S1 to Sn. Also, the capacitive parts D1 to Dn can be configured in various structures.

The plurality of capacitors C1 to Cn may have a different capacitance from one another, and the plurality of switches S1 to Sn can be operated individually.

The switches S1 to Sn and the capacitors C1 to Cn can be configured as illustrated in FIGS. 9 and 10, and the switches S1 to Sn can be arbitrarily controlled in a digital circuit.

In addition, both the method of increasing the resistance and the method of increasing the capacitance can be applied at the same time.

### Embodiment 3

The layout can be designed more simply by partially revising the structure of the first embodiment.

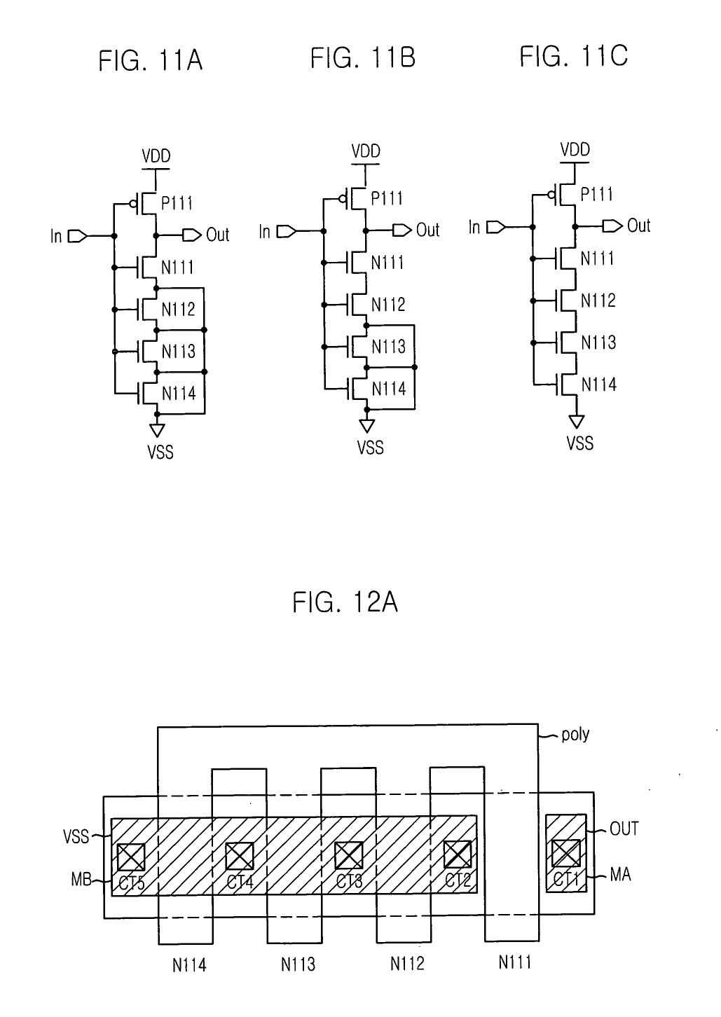

FIGS. 11A to 11C are circuit diagrams showing a driver for controlling a transfer transistor in accordance with a third embodiment of the present invention.

As shown, a CMOS inverter type driver includes one PMOS transistor P111 and four NMOS transistors N111 to N114 connected in series.

Although a basic structure is similar to the structure of FIG. 7C, sources of the NMOS transistors N111 to N114 are commonly connected to a ground voltage VSS, thereby forming a kind of a resistor.

In FIG. 11A, sources of the NMOS transistors N111 to N114 are commonly connected to the ground voltage VSS. In FIG. 11B, sources of the NMOS transistors N112 to N114 are commonly connected to the ground voltage VSS. In FIG. 11C, no sources of the NMOS transistors are connected to the ground voltage VSS.

In FIGS. 11A to 11C, the NMOS transistors are formed as many as the serial connection is possible, and the length L can be controlled using a metal contact and a metal line.

Accordingly, the W/L ratio is K in FIG. 11A, a half of K in FIG. 11B, and a quarter of K in FIG. C.

This means that the W/L ratio can be adjusted only through a partial revision of the metal line and the metal contact, without modifying the gate electrode.

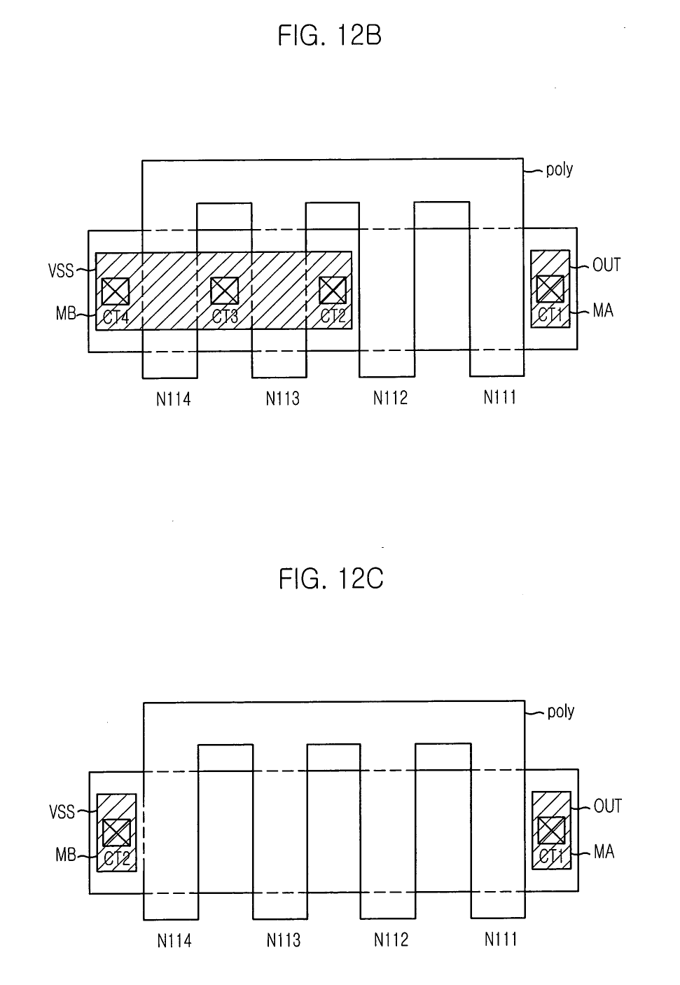

FIGS. 12A to 12C are layouts describing the driver as shown in FIGS. 11A to 11C.

Referring to FIG. 12A, a drain terminal of the NMOS transistor N111 is connected through the metal contact CT1 to the output terminal OUT formed of the metal line MA. The NMOS transistors N112 to N114 are connected through the contacts CT2 to CT5 to the ground voltage VSS formed of the metal line MB.

Referring to FIG. 12B, a drain terminal of the NMOS transistor N111 is connected through the metal contact CT1 to the output terminal OUT formed of the metal line MB. The NMOS transistors N112 to N114 are connected through the contacts CT2 to CT4 to the ground voltage VSS formed of the metal line MB.

At this time, a source terminal of the NMOS transistor N111 and a drain terminal of the transistor N112 are not connected to the ground voltage VSS.

Referring to FIG. 12C, a drain terminal of the NMOS transistor N111 is connected through the metal contact CT1 to the output terminal OUT formed of the metal line MA. A source terminal of the NMOS transistors N114 is connected through the contact CT2 to the ground voltage VSS formed of the metal line MB.

At this time, a source terminal of the NMOS transistor N111 and a drain terminal of the NMOS transistor N112, a source terminal of the NMOS transistor N112 and a drain terminal of the NMOS transistor N113, and a source terminal of the NMOS transistor N113 and a drain terminal of the NMOS transistor N114 are not connected to the ground voltage VSS.

As described above, during the increased falling time, a time margin for generation of an electric field allowing channel electrons to move to a floating diffusion node higher than the photodiode is increased. All channel electrons move to the floating diffusion node due to the electric field, thereby reducing partition noise.

Although the CMOS image sensor having four transistors and one photodiode has been described, the present invention is not limited to this configuration. That is, the present invention can be applied to all kinds of CMOS image sensors having the transfer transistors in the unit pixels.

According to the present invention, the partition noise in the CMOS image sensor can be reduced, thereby improving the performance of the CMOS image sensor.

The present application contains subject matter related to the Korean patent application No. KR 2005-15520, filed in the Korean Patent Office on Feb. 24, 2005, the entire contents of which being incorporated herein by reference.

While the present invention has been described with respect to the particular embodiments, it will be apparent to those skilled in the art that various changes and modifications may be made without departing from the scope of the invention as defined in the following claims.

What is claimed is:

1. A CMOS image sensor, comprising:
a unit pixel, including a transfer transistor controlled by a transfer control signal; and
a transfer control signal controller for controlling a rising and a falling times of the transfer control signal,
wherein the falling time of the transfer control signal is sufficiently increased to reduce a partition noise.

2. The CMOS image sensor as recited in claim 1, wherein the falling time of the transfer control signal is longer than twice the rising time of the transfer control signal.

3. The CMOS image sensor as recited in claim 1, wherein the unit pixel further includes a photodiode, a reset transistor, a drive transistor and a select transistor.

4. The CMOS image sensor as recited in claim 3, wherein the transfer control signal controller includes a CMOS type driver having a NMOS transistor.

5. The CMOS image sensor as recited in claim 4, wherein a size of the NMOS transistor is reduced in order to increase the falling time when the transfer transistor is turned off.

6. The CMOS image sensor as recited in claim 5, wherein the size of the NMOS transistor includes a W/L ratio, where the W and the L represent a channel width and a channel length, respectively.

7. The CMOS image sensor as recited in claim 6, wherein the channel length is increased to reduce the W/L ratio of the transfer transistor.

8. The CMOS image sensor as recited in claim 7, wherein the CMOS type driver includes a plurality of NMOS transistors connected in series to increase the channel length.

9. The CMOS image sensor as recited in claim 8, wherein at least two sources of the NMOS transistors connected in series are commonly connected to a ground voltage.

10. The CMOS image sensor as recited in claim 9, wherein the sources of the NMOS transistors are commonly connected to the ground voltage through a metal line.

11. The CMOS image sensor as recited in claim 3, further comprising a plurality of capacitive parts connected between a ground voltage and a common node which is connected between an output terminal of the transfer control signal controller and gates of the transfer transistors to thereby increase the falling time of the transfer transistor.

12. The CMOS image sensor as recited in claim 11, wherein each of the capacitive parts includes a capacitor and a switch connected in series.

13. The CMOS image sensor as recited in claim 12, wherein the plurality of switches are operated individually.

14. The CMOS image sensor as recited in claim 12, wherein each of the plural capacitors has a different capacitance.

15. The CMOS image sensor as recited in claim 11, wherein the transfer control signal controller includes a CMOS type driver.

16. A CMOS image sensor, comprising:
a plurality of unit pixels arranged in a column X a row form, each including a transfer transistor controlled by a transfer control signal; and
a transfer control signal controller for controlling a rising and a falling times of the transfer control signal; and
a plurality of capacitive parts connected between a ground voltage and a common node which is connected between an output terminal of the transfer control signal controller and gates of the transfer transistors to thereby increase the falling time of the transfer transistor when the transfer transistors contained in the unit pixels of the same row are turned off,
wherein, the plural unit pixels are disposed in the same row being controlled by the single transfer control signal controller.

17. The CMOS image sensor as recited in claim 16, wherein each of the capacitive parts includes a capacitor and a switch connected in series.

18. The CMOS image sensor as recited in claim 17, wherein the plurality of switches are operated individually.

19. The CMOS image sensor as recited in claim 17, wherein each of the plural capacitors has a different capacitance.

20. The CMOS image sensor as recited in claim 16, wherein the transfer control signal controller includes a CMOS type driver.
